(19) United States
(12) Patent Application Publication
(10) Pub. No.: US 2025/0324840 A1
(43) Pub. Date: Oct. 16, 2025

(54) DISPLAY APPARATUS

(71) Applicants: SONY GROUP CORPORATION, TOKYO (JP); SONY SEMICONDUCTOR SOLUTIONS CORPORATION, KANAGAWA (JP)

(72) Inventors: ICHIRO MORI, TOKYO (JP); GYONGSOK SONG, TOKYO (JP); HIROKAZU IMAI, TOKYO (JP); AKIRA OHMAE, TOKYO (JP); TETSUHIRO SAKAMOTO, KANAGAWA (JP)

(21) Appl. No.: 18/869,955

(22) PCT Filed: Apr. 18, 2023
(86) PCT No.: PCT/JP2023/015423

§ 371 Date: Nov. 27, 2024

(30) Foreign Application Priority Data
Jun. 6, 2022 (JP) 2022-091735

(51) Int. Cl. H10H 29/855; G02F 1/1335

(52) U.S. Cl. CPC H10H 29/855; G02F 1/133514; G02F 1/133553

(57) ABSTRACT

A display apparatus includes: a light source that emits light; a design layer that is disposed to oppose the light source, and in which a design is made on at least a surface of the design layer, the surface being on an opposite side of the light source; a light passage region that is disposed in the design layer at a position corresponding to the light source, that causes light emitted from the light source to pass therethrough, and that is visually unrecognizable at a viewing distance; and a light emission luminance control unit that controls light emission luminance of the light that is emitted from the light source and that passes through the light passage region to be more than or equal to a value obtained by multiplication of average design layer luminance of the design layer by an allowable limit value that causes the design to disappear.

### TECHNICAL FIELD

The present disclosure relates to a display apparatus.

### BACKGROUND ART

The following Patent Literature 1 discloses a liquid crystal display apparatus with a design sheet. The design sheet is attached to a surface of the liquid crystal display apparatus. The design sheet has a design that is identical to a surrounding design at a position at which the liquid crystal display apparatus is installed. When power is OFF, the liquid crystal display apparatus does not perform display. At this time, in the liquid crystal display apparatus, the design of the design sheet attached to the surface is visually recognizable. In contrast, when power is OFF, the liquid crystal display apparatus performs display. At this time, in the liquid crystal display apparatus, display that has been transmitted through the design sheet is visually recognizable.

### CITATION LIST

### Patent Literature

Patent Literature 1: Japanese Unexamined Patent Application Publication No. 2018-128581

### SUMMARY OF THE INVENTION

In the meantime, in the above-mentioned liquid crystal display apparatus, a light amount of display is reduced when light is transmitted through the design sheet. Additionally, display is superimposed on a design of the design sheet. For this reason, a display apparatus that prevents interference with a design at the time of non-display and that enables display of a vivid image or a vivid video picture without being influenced by the design.

A display apparatus according to one embodiment of the present disclosure includes: a light source that emits light; a design layer that is disposed to oppose the light source, and in which a design is made on at least a surface of the design layer, the surface being on an opposite side of the light source; a light passage region that is disposed in the design layer at a position corresponding to the light source, that causes light emitted from the light source to pass therethrough, and that is visually unrecognizable at a viewing distance; and a light emission luminance control unit that controls light emission luminance of the light that is emitted from the light source and that passes through the light passage region to be more than or equal to a value obtained by multiplication of average design layer luminance of the design layer by an allowable limit value that causes the design to disappear.

Furthermore, in the display apparatus according to one embodiment, the light emission luminance control unit performs control to satisfy the following expression.

Light emission luminance≥allowable limit value×average design layer luminance

### BRIEF DESCRIPTION OF THE DRAWINGS

FIG. 1 is a block diagram illustrating a display apparatus according to a first embodiment of the present disclosure.

FIG. 2 is a front diagram illustrating a light source and a design layer that constitute the display apparatus illustrated in FIG. 1.

FIG. 3 is a cross-sectional diagram illustrating the light source and the design layer that constitute the display apparatus illustrated in FIG. 1.

FIG. 4 is a front view for describing light emission luminance and average design layer luminance in the display apparatus illustrated in FIG. 1.

FIG. 5 is a schematic view for describing a viewing distance between the display apparatus illustrated in FIG. 1 and a viewer.

FIG. 6 is a schematic view for describing the spatial resolution of eyes of the viewer in the display apparatus according to a first embodiment.

FIG. 7 is a graph illustrating a relationship between light emission luminance and design luminance in the display apparatus according to the first embodiment.

FIG. 8 is a front diagram illustrating the design layer indicating a display state of the display apparatus according to the first embodiment.

FIG. 9 is a front diagram illustrating a design layer indicating a display state of a display apparatus according to a comparative example.

FIG. 10 is a front diagram illustrating a light source and a design layer that constitute a display apparatus according to a second embodiment of the present disclosure and corresponding to FIG. 2.

FIG. 11 is a cross-sectional diagram illustrating the light source and the design layer that constitute the display apparatus according to the second embodiment and corresponding to FIG. 3.

FIG. 12 is a block diagram illustrating a display apparatus according to a third embodiment of the present disclosure and corresponding to FIG. 1.

FIG. 13 is a block diagram illustrating a display apparatus according to a fourth embodiment of the present disclosure and corresponding to FIG. 1.

FIG. 14 is a cross-sectional diagram illustrating a light source, a design layer, and a light condensing optical system that constitute the display apparatus illustrated in FIG. 13.

FIG. 15 is a cross-sectional diagram illustrating a light source, a design layer, and a light condensing optical system that constitute a display apparatus according to a first modification example of the fourth embodiment and corresponding to FIG. 14.

FIG. 16 is a cross-sectional diagram illustrating a light source, a design layer, and a light condensing optical system that constitute a display apparatus according to a second modification example of the fourth embodiment and corresponding to FIG. 14.

FIG. 17 is a cross-sectional diagram illustrating a light source, a design layer, and a light condensing optical system that constitute a display apparatus according to a third modification example of the fourth embodiment and corresponding to FIG. 14.

FIG. 18 is a block diagram illustrating a display apparatus according to a fifth embodiment of the present disclosure and corresponding to FIG. 1.

FIG. 19 is a front diagram illustrating a design layer indicating a display state when a viewer views/listens to the display apparatus illustrated in FIG. 18 from a front direction.

FIG. 20 is a front diagram illustrating the design layer indicating a display state when the viewer views/listens to the display apparatus illustrated in FIG. 18 from a front and oblique direction and corresponding to FIG. 19.

FIG. 21 is a block diagram illustrating a display apparatus according to a sixth embodiment of the present disclosure and corresponding to FIG. 1.

FIG. 22 is a front diagram illustrating a design layer indicating a display state in which a color is changed by a color change layer in the display apparatus illustrated in FIG. 21 and corresponding to FIG. 8.

FIG. 23 is a first step cross-sectional view for describing a method of manufacturing a design layer that constitutes a display apparatus according to a seventh embodiment of the present disclosure.

FIG. 24 is a second step cross-sectional view corresponding to FIG. 23.

FIG. 25 is a third step cross-sectional view corresponding to FIG. 23.

FIG. 26 is a fourth step cross-sectional view corresponding to FIG. 23.

FIG. 27 is a third step plan view corresponding to FIG. 25.

FIG. 28 is a fourth step plan view corresponding to FIG. 26.

### MODES FOR CARRYING OUT THE INVENTION

Some embodiments of the present disclosure will be described in detail below with reference to drawings. Note that the description will be given in the following order.

### 1. First Embodiment

In a first embodiment, an example in which the present technology is applied to a display apparatus will be described. In the first embodiment, a description will be given of a system configuration of the whole of the display apparatus, and a configuration of a light source and a design layer that constitute the display apparatus.

### 2. Second Embodiment

In a second embodiment, a description will be given of an example in which the configuration of the light source is changed in the display apparatus according to the first embodiment.

### 3. Third Embodiment

In a third embodiment, a description will be given of an example in which the display apparatus according to the first embodiment or the second embodiment is provided with a light emission luminance correction unit.

### 4. Fourth Embodiment

In a fourth embodiment, a description will be given of an example in which the display apparatus according to any of the first to third embodiments is provided with a light condensing optical system. In the fourth embodiment, a description will be also given of some modification examples regarding the light condensing optical system.

### 5. Fifth Embodiment

In a fifth embodiment, a description will be given of an example in which the display apparatus according to any of the first to fourth embodiments is provided with an operation detection unit and a picture signal control unit.

### 6. Sixth Embodiment

In a sixth embodiment, a description will be given of an example in which the display apparatus according to any of the first to fifth embodiments includes, in the design layer, a color change layer that is changed in color by temperature conversion.

### 7. Seventh Embodiment

In a seventh embodiment, a description will be given of a preferable method of manufacturing the design layer in the display apparatus according to any of the first to sixth embodiments.

### 8. Other Embodiments

### 1. First Embodiment

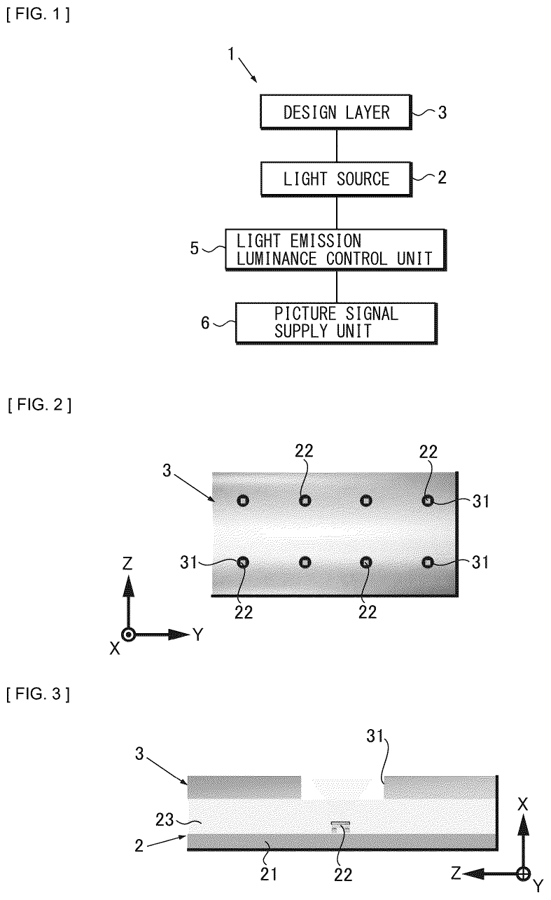

A display apparatus 1 according to a first embodiment of the present disclosure will be described with reference to FIGS. 1 to 9. An X arrow direction illustrated in the drawings appropriately represents one planer direction of the display apparatus 1 placed on a plane for convenience's sake. A Y arrow direction represents another planer direction orthogonal to the X arrow direction. In addition, a Z arrow direction represents an upper direction orthogonal to the X arrow direction, and the Y arrow direction. That is, the X arrow direction, the Y arrow direction, and the Z arrow direction respectively coincide with an X axis direction, a Y axis direction, a Z axis direction in a three-dimensional coordinate system. Note that each direction is illustrated for easier understanding of the description, and does not limit a direction of the present technology.

### [Configuration of Display Apparatus 1]

### (1) Overall Configuration of Display Apparatus 1

FIG. 1 illustrates an example of an overall configuration of the display apparatus 1 according to the first embodiment. The display apparatus 1 according to the first embodiment is configured as a single apparatus or an apparatus incorporated into at least a portion of a wall, a pillar, a piece of furniture, a machine product, an electronic product, or the like. The display apparatus 1 as the apparatus incorporated into the wall or the pillar is installable in a room, and furthermore, is installable outside the room. The display apparatus 1 is constructed to include a light source 2, a design layer 3, and a light emission luminance control unit 5. A light transmission region 31 is further disposed in the design layer 3. The display apparatus 1 further includes a picture signal supply unit 6. Note that the picture signal supply unit 6 may be built into the display apparatus 1 as a display system, or may be constructed as an external apparatus of the display apparatus 1.

When the display apparatus 1 starts to perform display, the light source 2 emits light toward the design layer 3. Light emitted from the light source 2 is transmitted through a portion of the design layer 3. The light that has been transmitted is output to one side of the design layer 3 on the opposite side of the light source 2 as optical information such as a character, a color, an image, and a video picture. In a case where a viewer is present around the display apparatus 1, the optical information output from the display apparatus 1 is visually recognized by the viewer.

The design layer 3 is disposed to oppose the light source 2. A design is made on at least a surface of the design layer 3 on the opposite side of the light source 2. The design includes, for example, at least one or more selected from a color, a pattern, a wood grain, marble, and metal. That is, for example, the design may be formed in a single color, or may be formed in combination of the color and the pattern. In a case of the wood grain, the design is formed from wood having the wood grain. In addition, the design may be formed from a film in which the wood grain is drawn or by printing of a wood grain pattern. The design is not limited to the case of the wood grain, and is formed from a material itself, from a film in which a material pattern is drawn, or by printing of the material pattern.

The light emission luminance control unit 5 controls light emission luminance of light emitted from the light source 2 on the basis of a picture signal supplied from the picture signal supply unit 6. The light emission luminance control unit 5 according to the first embodiment controls light emission luminance of light that has been transmitted through the design layer 3 to cause the design of the design layer 3 to disappear with respect to a viewer H (refer to FIG. 5) who is viewing to the display apparatus 1 at a viewing distance L. Here, the light emission luminance that causes the design to disappear is used in the meaning that, when optical information is output, the design of the design layer 3 is obliterated so that the viewer visually recognizes only the optical information vividly without being distracted by the design.

The light emission luminance control unit 5 is constructed to include at least an input circuit, a control circuit, and an output circuit, which are not illustrated. The input circuit is supplied with a picture signal from the picture signal supply unit 6. The control circuit generates a control signal that causes the design to disappear on the basis of the supplied picture signal. The output circuit outputs the generated control signal to the light source 2. The control circuit is constructed to have a hardware configuration using a dedicated circuit. Additionally, the control circuit includes at least a central processing unit (CPU) and a storage apparatus, and may be constructed to have a software configuration using software to generate a control signal from a picture signal.

Subsequently, each constituent element of the display apparatus 1 will be described in detail.

### (2) Configuration of Light Source 2

FIG. 2 illustrates an example of a configuration of the light source 2 and the design layer 3 that constitute the display apparatus 1 illustrated in FIG. 1, when viewed from the front side. FIG. 3 illustrates an example of a cross-sectional configuration of the light source 2 and the design layer 3.

As illustrated in FIGS. 2 and 3, the light source 2 is configured to include at least a substrate 21, a light emitting device 22, and a sealing body 23. As illustrated in FIG. 2, the light emitting device 22 is mounted on a surface of the substrate 21 on the design layer 3 side. Wiring extending in a thickness direction (the X arrow direction here) is disposed on the substrate 21. The wiring is not illustrated. The wiring supplies a control signal from the light emission luminance control unit 5 to the light emitting device 22. As the substrate 21, it is possible to practically use a semiconductor substrate such as a single crystal silicon substrate, a circuit substrate such as a printed wiring substrate, or the like.

In the first embodiment, a micro light emitting diode (μLED) is used in the light emitting device 22. A plurality of light emitting devices 22 is arrayed at regular intervals in the Y arrow direction and the Z arrow direction. That is, the light source 2 is structured in a light emitting diode array. A numeric value is not specifically limited, but an array pitch of the light emitting devices 22 is set to be, for example, 0.6 mm or more and 1.8 mm or less here. Although a detailed structure is omitted, the light emitting devices 22 that enables emission of red light, green light, and blue light are used here. That is, it is possible for the display apparatus 1 to perform white and black display and color display.

The sealing body 23 is disposed on the surface of the substrate 21 on the design layer 3 side to cover the light emitting devices 22. The sealing body 23 seals and protects the light emitting devices 22.

### (3) Configuration of Design Layer 3

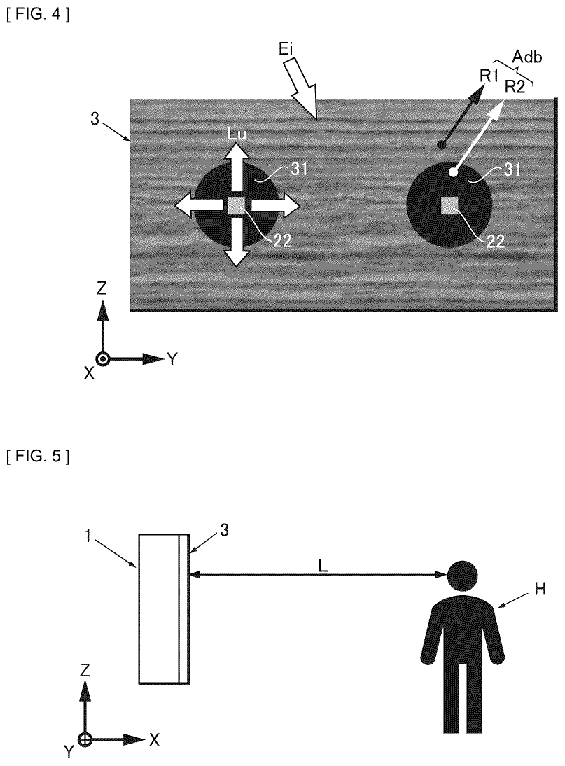

FIG. 4 illustrates an example of a configuration when the light source 2 and the design layer 3 are viewed from the front side in an enlarged manner. As illustrated in FIGS. 2 to 4, the design layer 3 is disposed on the sealing body 23 of the light source 2 on the opposite side of the light emitting device 22. The design layer 3 is formed of, for example, wood having a plate like shape and the wood grain as the design among the above-mentioned examples.

The light transmission region 31 is disposed in the design layer 3 at a position corresponding to the light source 2, specifically, a position corresponding to the light emitting device 22. A plurality of light passage regions 31 is arrayed similarly to the light emitting devices 22, and the light passage region 31 is disposed for each light emitting device 22. More specifically, the light passage region 31 is disposed so that a center position of the light passage region 31 is matched with an optical axis of light emitted from the light emitting device 22. The light passage region 31 is disposed in a region of the design layer 3 in which the design is wanted to disappear (a region in which the design is obliterated) when the display apparatus 1 performs display. Note that in a case where a view angle is intentionally changed or the like, it is possible to intentionally offset the optical axis of the light emitting device 22 and the center position of the light passage region 31 with each other.

In the first embodiment, the light passage region 31 is formed as a light passage hole penetrating the design layer 3 in a thickness direction and having an identical inner diameter in the thickness direction. An aperture shape of the light passage region 31 here is formed as a circular shape when viewed from the X arrow direction (hereinafter simply referred to as “in a front view”). Note that the aperture shape of the light passage region 31 is not limited to the circular shape. The aperture shape may be formed as, for example, an ellipsoidal shape, a rectangular shape, a triangle shape, or a polygon shape that is a pentagonal or more shape, in a plan view.

FIG. 5 is a schematic view for describing a viewing distance L between the display apparatus and the viewer H. In the display apparatus 1, the light passage region 31 causes light emitted from the light source 2 to pass therethrough in the X arrow direction. Additionally, as illustrated in FIG. 5, the light passage region 31 is not recognized from the viewer H at the viewing distance L. The viewing distance L is a distance from the display apparatus 1, more specifically, the light passage region 31 in the design layer 3 to an eye of the viewer H.

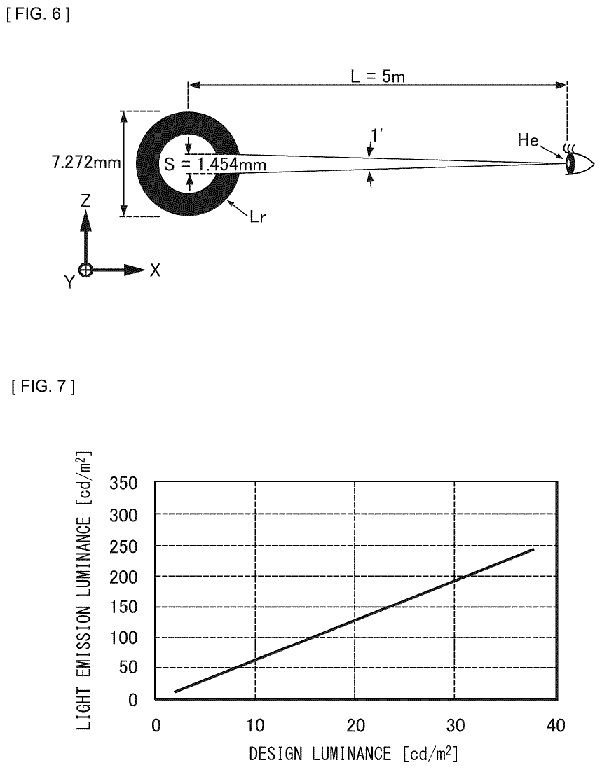

FIG. 6 is a schematic view for describing the spatial resolution of the eye of the viewer H. A threshold for whether or not the light passage region 31 is visually recognizable is determined by the spatial resolution (eyesight) of an eye He of the viewer H and the viewing distance L. As illustrated in FIG. 6, for example, eyesight of 1 is an eyesight value that enables clear discrimination of a gap S of a Landolt Ring Lr per degree of visual angle at the viewing distance L of 5 m (for example, refer to the following Uniform Resource Locator (URL)).
URL: https://www.nidek.co.jp/eyestory/eye_5.html

With the eyesight of 1, an external dimension of the Landolt Ring Lr is 7.272 mm, and the gap S is 1.454 mm. That is, if the light passage region 31 is formed to have an aperture dimension that is smaller than a dimension of the gap S, it is impossible for the viewer H having the eyesight of 1 to visually recognize the light passage region 31 at the viewing distance L of 5 m. At this time, the light source 2 is in a non-lit state where it does not emit light.

It is possible to obtain a minimum aperture ratio OR of the light passage region 31 that enables viewing on the basis of the adequate viewing distance L. The aperture ratio OR is calculated from the following expression <1>.

$$OR = π \times {( Φ / 2 )}^{2} / {pp}^{2} \qquad 〈 1 〉$$

In this expression, Φ represents an aperture diameter, and pp represents a pixel pitch and corresponds here to an array pitch of the light passage regions 31 or an array pitch of the light emitting devices 22.

For example, to obtain the aperture ratio OR in a case where the array pitch of the light passage regions 31 corresponds to a vertical resolution 2160 pitch for ultra-high-definition television (UHDTV: 4K) at the viewing distance L of 1V with the eyesight of 1, spatial resolution A is represented by the following expression <2>.

$$A = 1454 µm \times 1 / V A \times ( L / 5 m ) \qquad 〈 2 〉$$

In this expression, VA represents eyesight. Additionally, the viewing distance L is expressed by the following expression <3>.

$$L = α V \times α \times 2160 \times pp \qquad 〈 3 〉$$

As a constraint condition, when the aperture diameter Φ and the spatial resolution A are in a relationship of the aperture diameter Φ∝the spatial resolution A, the aperture diameter Φ is expressed by the following expression <4>.

$$Φ = n A \qquad 〈 4 〉$$

In this expression, α and n are coefficients.

By substituting the above-mentioned expressions <2> to <4> into the above-mentioned expression <1>, a minimum aperture ratio OR of the viewable light passage region 31 based on the adequate viewing distance L is 31%. That is, assuming that the eyesight of the viewer H is “1” and the viewing distance L is “V”, in a case where the aperture ratio OR of the light passage region 31 is less than 31%, the light passage region 31 is visually unrecognizable from the viewer H.

### (4) Configuration of Light Emission Luminance Control Unit 5

The light emission luminance control unit 5 illustrated in FIG. 1 controls light emission luminance Lu of light that has passed through the light passage region 31 of the design layer 3 on the basis of the following expression <5>.

Light emission luminance Lu≥allowable limit value α×average design layer luminance Adb <5>

That is, the light emission luminance control unit 5 controls the light emission luminance Lu of light that has been emitted from the light source 2 and has passed through the light passage region 31 to be equal to or more than luminance obtained by multiplying the average design layer luminance Adb of the design layer 3 by the allowable limit value α that causes the design to disappear.

The average design layer luminance Adb is an average value of reflection R1 in the design and reflection R2 in the light passage region 31 with respect to external light illuminance Ei of external light with which the design of the design layer 3 is irradiated.

The allowable limit value a is obtained by an experiment with respect to the design of the design layer 3. FIG. 7 illustrates an example of a relationship between light emission luminance of light emitted from the light source 2 and design luminance of the design of the design layer 3. An abscissa axis indicates the design luminance [cd/m²]. An ordinate axis indicates the light emission luminance [cd/m²]. In a case where a general design such as wood, marble, and metal exemplified above is made on the design layer 3 and the light emission luminance Lu is six times or more and seven times or less the average design layer luminance Adb, it is possible to cause the design to disappear from the viewer H located at the viewing distance L. That is, the design of the design layer 3 is obliterated and it is possible for the viewer H to vividly visually recognize the optical information emitted from the light source 2. Therefore, the allowable limit value α is set to be 6 or greater and 7 or less.

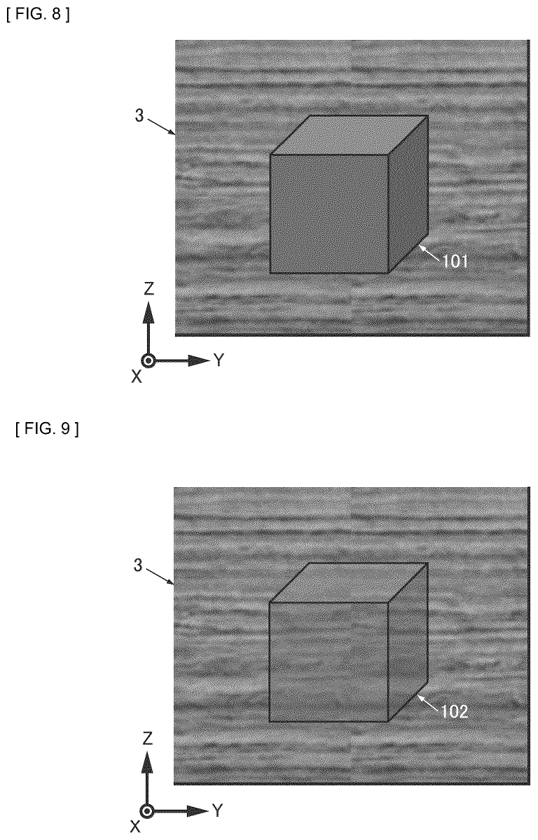

FIG. 8 illustrates an example of the design layer 3 indicating a display state of the display apparatus 1 according to the first embodiment. As illustrated in FIG. 8, the display apparatus 1 according to the first embodiment vividly displays optical information 101 output to the design of the design layer 3. The optical information 101 mentioned herein is an image or video picture of a cube. Since the optical information 101 is controlled with the adequate light emission luminance Lu even when it is output (displayed) so as to be superimposed on the design of the design layer 3. It causes the design to disappear and is output as vivid optical information. That is, it is possible for the viewer H to vividly visually recognize only the optical information 101 without being distracted by the design on which the optical information 101 is superimposed.

FIG. 9 illustrates an example of a design layer indicating a display state of a display apparatus according to a comparative example. In the display apparatus according to the comparative example illustrated in FIG. 9, when optical information 102 that is output to the design of the design layer 3 is output so as to be superimposed on the design, a portion of the design is seen and the optical information 102 is not vividly displayed. The optical information 102 is an image or video picture of a cube similarly to the optical information 101.

### [Actions and Effects]

The display apparatus 1 according to the first embodiment includes the light source 2, the design layer 3, the light passage region 31, and the light emission luminance control unit 5, as illustrated in FIG. 1. The light source 2 emits light. The design layer 3 is disposed to oppose the light source 2. The design has been made on at least the surface of the design layer 3 on the opposite side of the light source 2. The light passage region 31 is disposed in the design layer 3 at a position corresponding to the light source 2. The light passage region 31 causes light emitted from the light source 2 to pass therethrough. Additionally, the light passage region 31 is visually unrecognizable at the viewing distance L (refer to FIG. 5). The light emission luminance control unit 5 controls the light emission luminance Lu of light, which has been emitted from the light source 2 and has passed through the light passage region 31, to be more than or equal to luminance obtained by multiplying the average design layer luminance Adb of the design layer 3 by the allowable limit value a that causes the design to disappear. In other words, the light emission luminance control unit 5 performs control to satisfy the following expression.

Light emission luminance Lu≥allowable limit value α×average design layer luminance Adb

As a result, at the time of non-display of the display apparatus 1, the light passage region 31 is visually unrecognizable at the viewing distance L and thus does not interfere with the design of the design layer 3. The time of non-display mentioned herein is time when light is not emitted from the light source 2 and the optical information 101 (refer to FIG. 8) is not output. In contrast, at the time of display of the display apparatus 1, the light emission luminance Lu of light that has passed through the light passage region 31 is controlled at the viewing distance L, and it is possible to cause the design of the design layer 3 to disappear. Hence, as illustrated in FIG. 8, even when the optical information 101 is superimposed on the design, it is possible to output (display) the optical information 101 as a vivid image, a vivid video picture, or the like without being influenced by the design. That is, it is possible for the display apparatus 1 to prevent interference with the design at the time of non-display and display the vivid image or the vivid video picture without being influenced by the design.

For example, in a high-class hotel in which the installation of an electrical apparatus, an electronic apparatus, and the like is desired to be avoided as much as possible, it is possible to use the display apparatus 1 that is incorporated into a wall or a table. It is possible for the display apparatus 1 that is incorporated into the wall or the table in such a manner to display a vivid image or a vivid video picture as necessary without impairing the design or the beauty. Additionally, with use of the display apparatus 1, it is possible to perform various kinds of stage direction. Furthermore, since the display apparatus 1 outputs the optical information 101 by causing the design of the design layer 3 to disappear, it is possible to vividly display especially a cube image or a cube video picture in a state where the optical information 101 emerges from the design of the design layer 3.

Additionally, in the display apparatus 1, as illustrated in FIGS. 2 to 4, the light passage region 31 includes a light passage hole formed in at least a portion of the design layer 3 in the thickness direction. It is possible to easily produce the light passage hole in the design layer 3. Additionally, it is possible for the light passage hole to cause light emitted from the light source 2 to pass therethrough efficiently. Hence, it is possible to easily implement the display apparatus 1.

Additionally, in the display apparatus 1, as illustrated in FIGS. 4 and 8, the design of the design layer 3 includes at least one or more selected from the color, the pattern, the wood grain, the marble, and the metal. Hence, it is possible to incorporate the display apparatus 1 into a product including a structure such as a wall and a pillar, an apparatus such as an electrical apparatus, an electronic apparatus, and a machine apparatus, a desk, a chair, and a stationary article by adapting the display apparatus 1 to a design under an environment. Furthermore, for example, it is possible to use the display apparatus 1 as a stationary article.

Additionally, in the display apparatus 1, as illustrated in FIG. 3, the light source 2 is a light-emitting diode array. With the light-emitting diode, it is possible to obtain high light emission luminance. Hence, in the display apparatus 1, as illustrated in FIG. 8, it is possible to obtain vivid optical information 101.

Additionally, in the display apparatus 1, as illustrated in FIGS. 1 and 7, the allowable limit value α is set to be 6 or more and 7 or less in the control of the light emission luminance Lu (refer to the above-mentioned expression <5>) of the light emission luminance control unit 5. Hence, at the time of display of the display apparatus 1, the light emission luminance Lu of light that has passed through the light passage region 31 is controlled at the viewing distance L, and it is possible to easily cause the design of the design layer 3 to disappear. Additionally, as illustrated in FIG. 8, even when the optical information 101 is superimposed on the design, it is possible to output (display) the optical information 101 as a vivid image, a vivid video picture, or the like without being influenced by the design.

Furthermore, in the display apparatus 1, the aperture ratio OR of the light passage region 31 in the design layer 3 illustrated in FIGS. 2 to 4 (refer to the above-mentioned expression <1>) is set to be less than 31% at the viewing distance L of 1V with the eyesight of 1 (refer to FIGS. 5 and 6). Under such a condition, it is not possible for the viewer H to recognize the light passage region 31 at the adequate viewing distance L. For this reason, it is possible for the display apparatus 1 to prevent interference with the design at the time of non-display and display the vivid image or the vivid video picture without being influenced by the design.

Furthermore, as illustrated in FIG. 1, the display apparatus 1 further includes a picture signal supply unit 6 that supplies a picture signal to be superimposed on the design of the design layer 3 to the light emission luminance control unit 5. Therefore, it is possible to more easily construct a display system including the picture signal supply unit 6 in the display apparatus 1.

### 2. Second Embodiment

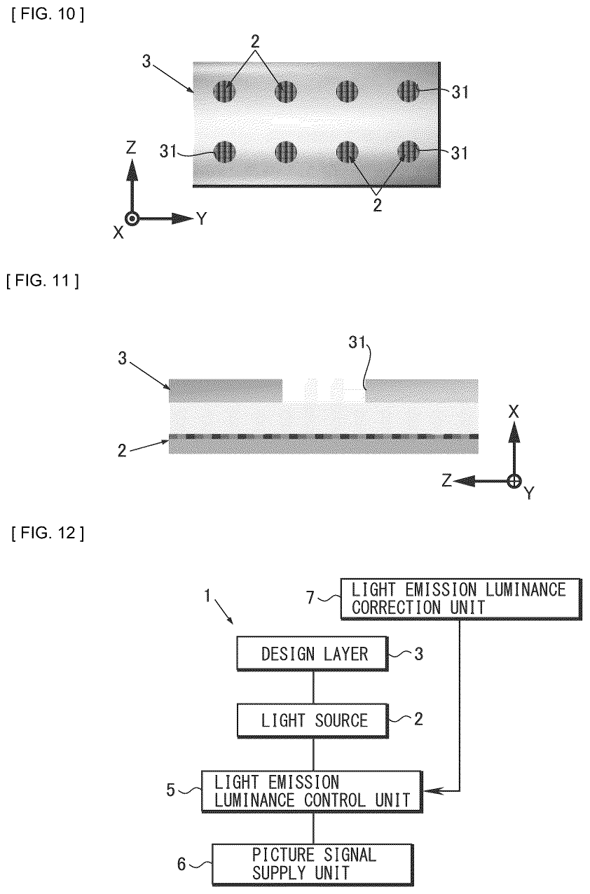

A display apparatus 1 according to a second embodiment of the present disclosure will be described with reference to FIGS. 10 to 11. Note that, in the second embodiment and other embodiments that will be subsequently described, a constituent element that is identical or substantially identical to that of the display apparatus 1 according to the first embodiment is denoted by an identical sign, and an overlapping description is omitted.

### [Configuration of Display Apparatus 1]

FIG. 10 illustrates an example of a configuration when the light source 2 and the design layer 3 that constitute the display apparatus 1 illustrated in FIG. 1 are viewed from the front side. FIG. 11 illustrates an example of a cross-sectional configuration of the light source 2 and the design layer 3. In the display apparatus 1 according to the second embodiment, a liquid crystal display (LCD) is used in the light source 2. The liquid crystal display is disposed to oppose the design layer 3 in the whole region in which the optical information 101 (refer to FIG. 8) is output.

Alternatively, an organic light emitting diode (OLED) display may be used in the light source 2. The organic liquid crystal display may have flexibility.

Constituent elements other than the above-mentioned constituent elements are identical or substantially identical to those of the display apparatus 1 according to the first embodiment.

### [Actions and Effects]

The display apparatus 1 according to the second embodiment enables obtaining of actions and effects similar to those obtained by the display apparatus 1 according to the first embodiment.

Additionally, in the display apparatus 1, as illustrated in FIGS. 10 and 11, the liquid crystal display (or the organic EL display) is used in the light source 2. In the liquid crystal display, pixels are arrayed on the whole surface of an effective display region in comparison with an array of the light emitting devices 22 in the light source 2 of the display apparatus 1 according to the first embodiment. That is, an array pitch of the pixels is smaller than the array pitch of the light passage regions 31 in the design layer 3. For this reason, since it is possible to easily dispose the design layer 3 so as to oppose the light source 2 without the need for alignment between the light source 2 and the light passage region 31, it is possible to simply implement the display apparatus 1.

Additionally, it is possible for the display apparatus 1 to selectively display pixels of the liquid crystal EL display adopted in the light source 2 at a position corresponding to the light passage region 31 in the design layer 3. By adopting such a display driving method, it is possible to reduce power consumption of the display apparatus 1 more significantly than that in a case of performing display on the whole surface of a display region of the liquid crystal display.

Furthermore, in the display apparatus 1, an organic EL display having flexibility may be adopted in the light source 2. In this case, for example, it is possible to form a curved surface shape in the design layer 3, and diversify the shape of the display apparatus 1. Additionally, in the display apparatus 1, it is possible to use a high-resolution μLED display in the light source 2 regardless of whether or not the high-resolution μLED display has flexibility.

### 3. Third Embodiment

A display apparatus 1 according to a third embodiment of the present disclosure will be described with reference to FIG. 12.

### [Configuration of Display Apparatus 1]

FIG. 12 illustrates an example of an overall configuration of the display apparatus 1 according to the third embodiment. The display apparatus 1 according to the third embodiment includes a light emission luminance correction unit. 7. The light emission luminance correction unit 7 includes a luminance meter that measures average design layer luminance Adb. After measuring the average design layer luminance Adb, the light emission luminance correction unit 7 transmits, to the light emission luminance control unit 5, a correction signal for correcting the light emission luminance Lu to be adequate luminance corresponding to a level of the average design layer luminance Adb. The light emission luminance control unit 5 controls the light emission luminance Lu to be adequate luminance on the basis of the correction signal.

The light emission luminance correction unit 7 is disposed adjacent to the light passage region 31 in the design layer 3, or at a position away from the design layer 3. The light emission luminance correction unit 7 is connected to the light emission luminance control unit 5 in a wired or wireless manner, and has a system of transmitting the correction signal.

Additionally, the light emission luminance correction unit 7 may include, instead of the above-mentioned luminance meter, an illuminance meter that measures environmental illuminance around the design layer 3 and preliminarily measured reflectance data of the design layer 3. On the basis of a result of calculating the average design layer luminance Adb from measured values by the illuminance meter and the reflectance data of the design layer 3, the light emission luminance correction unit 7 transmits the correction signal to the light emission luminance control unit 5.

Constituent elements other than the above-mentioned constituent elements are identical or substantially identical to those of the display apparatus 1 according to the first embodiment or the second embodiment.

### [Actions and Effects]

The display apparatus 1 according to the third embodiment enables obtaining of actions and effects similar to those obtained by the display apparatus 1 according to the first embodiment or the second embodiment.

Additionally, the display apparatus 1 includes the light emission luminance correction unit 7 as illustrated in FIG. 12. The light emission luminance correction unit 7 corrects the light emission luminance Lu on the basis of at least one or more selected from the average design layer luminance Adb measured by the luminance meter, the environmental illuminance around the design layer 3, which is measured by the illuminance meter, or the preliminarily measured reflectance data of the design layer 3. Therefore, the display apparatus 1 controls the light emission luminance Lu while correcting the light emission luminance Lu as appropriate, and can thereby output the stable optical information 101 (refer to FIG. 8) without being influenced by a change in brightness around the design layer 3.

### 4. Fourth Embodiment

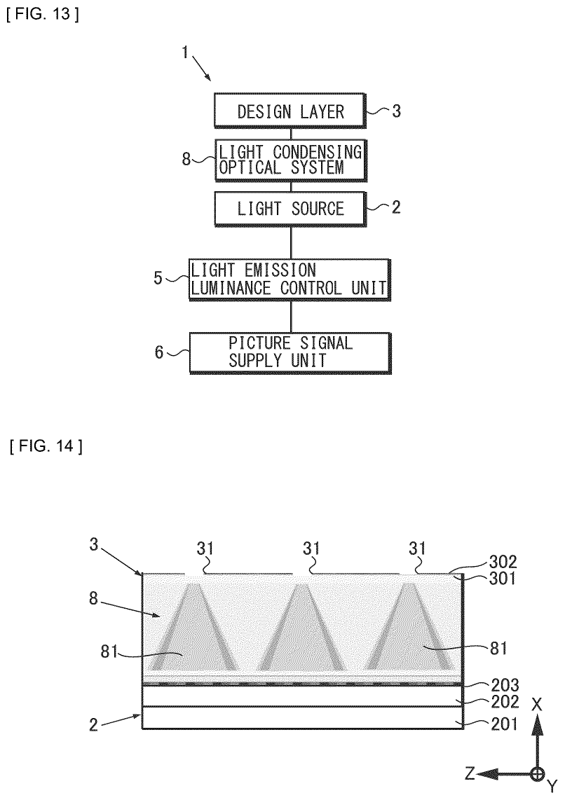

A display apparatus 1 according to a fourth embodiment of the present disclosure will be described with reference to FIGS. 13 to 17.

### [Configuration of Display Apparatus 1]

FIG. 13 illustrates an example of an overall configuration of the display apparatus 1 according to the fourth embodiment. FIG. 14 illustrates an example of a cross-sectional configuration of the light source 2 and the design layer 3. The display apparatus 1 according to the fourth embodiment corresponds to the display apparatus 1 according to the first embodiment further including a light condensing optical system 8. The light condensing optical system 8 is disposed between the light source 2 and the design layer 3. It is possible for the light condensing optical system 8 to increase luminance of light emitted from the light source 2.

Here, a liquid crystal display is used in the light source 2 similarly to the light source 2 of the display apparatus 1 according to the second embodiment. The light source 2 includes at least a backlight 201, liquid crystals 202, and a color filter 203. The liquid crystals 202 are disposed on the design layer 3 side of the backlight 201. The color filter 203 is disposed on the design layer 3 side of the liquid crystals 202. Note that an organic EL display may be used as a display.

Here, the design layer 3 includes a base 301, and a design 302 disposed in the base 301 on the opposite side of the light source 2. The base 301 is formed of a substrate having light transmittivity higher than that of the design 302. For example, a transparent glass substrate or a resin substrate is used in the base 301. The design 302 is formed from a film or by printing as described above. Note that, in a case where the light emitting device 22 is used in the light source 2 of the display apparatus 1 according to the first embodiment, the base 301 is only required to include a light transmission part at least at a position corresponding to the light source 2 or the light passage region 31.

A light guiding fiber (fiber optical plate (FOP)) 81 is used in the light condensing optical system 8. A light guiding fiber 81 is formed to have a cross-section shape whose diameter decreases from the light source 2 toward the design layer 3. That is, in the light condensing optical system 8, light emitted from the light source 2 is condensed toward the light passage region 31 in the design layer 3.

Constituent elements other than the above-mentioned constituent elements are identical or substantially identical to those of the display apparatus 1 according to the first embodiment.

### [Actions and Effects]

The display apparatus 1 according to the fourth embodiment enables obtaining of actions and effects similar to those obtained by the display apparatus 1 according to the first embodiment.

Additionally, the display apparatus 1 includes the light condensing optical system 8 as illustrated in FIGS. 13 and 14. The light condensing optical system 8 is disposed between the light source 2 and the design layer 3. The light condensing optical system 8 enables condensing of light emitted from the light source 2. Hence, it is possible for the display apparatus 1 to increase the light emission luminance Lu and display a video image or a vivid video picture as the optical information 101 (refer to FIG. 8).

### First Modification Example

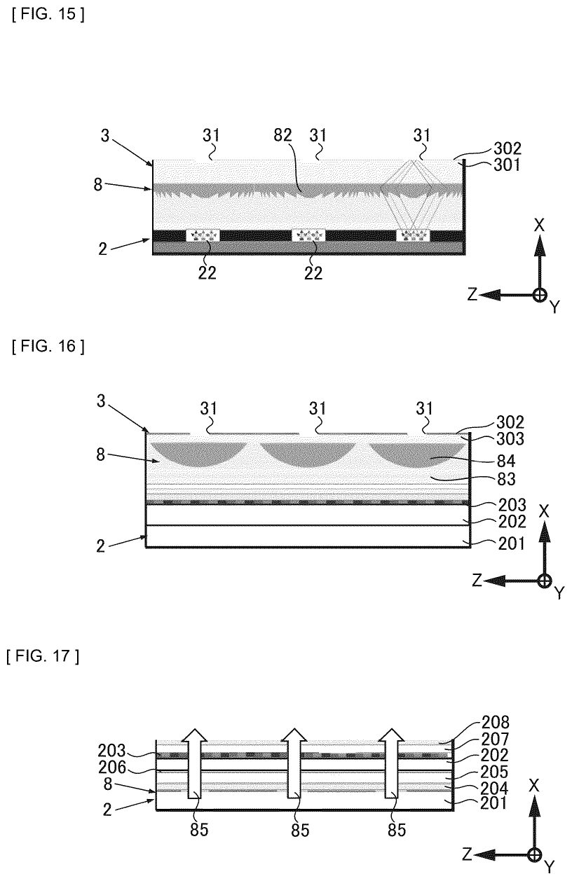

A display apparatus 1 according to a first modification example of the fourth embodiment of the present disclosure is now described. FIG. 15 illustrates an example of a cross-sectional configuration of the light source 2 and the design layer 3 in the display apparatus 1 according to the first modification example. In the display apparatus 1 according to the first modification example, a condensing lens 82 is used in the light condensing optical system 8. More specifically, a Fresnel lens that enables reduction of a thickness in the optical axis direction is used in the light condensing optical system 8. Note that the condensing lens 82 is not limited to the Fresnel lens, and a typical condensing lens such as a convex lens may be used. The plurality of arrayed light emitting devices 22 is used in the light source 2 similarly to the light source 2 of the display apparatus 1 according to the first embodiment.

Constituent elements other than the above-mentioned constituent elements are identical or substantially identical to those of the display apparatus 1 according to the fourth embodiment.

### [Actions and Effects]

The display apparatus 1 according to the first modification example enables obtaining of actions and effects similar to those obtained by the display apparatus 1 according to the fourth embodiment.

### Second Modification Example

A display apparatus 1 according to a second modification example of the fourth embodiment of the present disclosure is now described. FIG. 16 illustrates an example of a cross-sectional configuration of the light source 2 and the design layer 3 in the display apparatus 1 according to the second modification example. In the display apparatus 1 according to the second modification example, a dual brightness enhancement film (DBEF) 83, a condensing lens 84, and a mirror 303 are used in the light condensing optical system 8.

The DBEF 83 is disposed on the light source 2 side. The DBEF 83 condenses light utilizing double reflection and a refractive index of light when light emitted from the light source 2 passes through the inside of the film, and enables increase of luminance. The condensing lens 84 is disposed on the design layer 3 side. It is possible for the condensing lens 84 to further condense light with increased luminance.

A liquid crystal display is used in the light source 2 similarly to the light source 2 of the display apparatus 1 according to the fourth embodiment.

Constituent elements other than the above-mentioned constituent elements are identical or substantially identical to those of the display apparatus 1 according to the fourth embodiment.

### [Actions and Effects]

The display apparatus 1 according to the second modification example enables obtaining of actions and effects similar to those obtained by the display apparatus 1 according to the fourth embodiment.

### Third Modification Example

A display apparatus 1 according to a third modification example of the fourth embodiment of the present disclosure is now described. FIG. 17 illustrates an example of a cross-sectional configuration of the light source 2 and the design layer 3 in the display apparatus 1 according to the third modification example. In the display apparatus 1 according to the third modification example, a liquid crystal display is used in the light source 2, and a mirror aperture 85 disposed in the backlight 201 is used in the light condensing optical system 8.

The liquid crystal display as the light source 2 is formed so that the backlight 201, a polarization plate 204, a liquid crystal glass 205, a thin-film transistor (TFT) 206, the liquid crystals 202, the color filter 203, a liquid crystal cover glass 207, and a polarization plate 208 are sequentially laminated. The mirror aperture 85 is disposed between the backlight 201 and the polarization plate 204. It is possible for the mirror aperture 85 to condense light emitted from the backlight 201.

Constituent elements other than the above-mentioned constituent elements are identical or substantially identical to those of the display apparatus 1 according to the fourth embodiment.

### [Actions and Effects]

The display apparatus 1 according to the third modification example enables obtaining of actions and effects similar to those obtained by the display apparatus 1 according to the fourth embodiment.

### 5. Fifth Embodiment

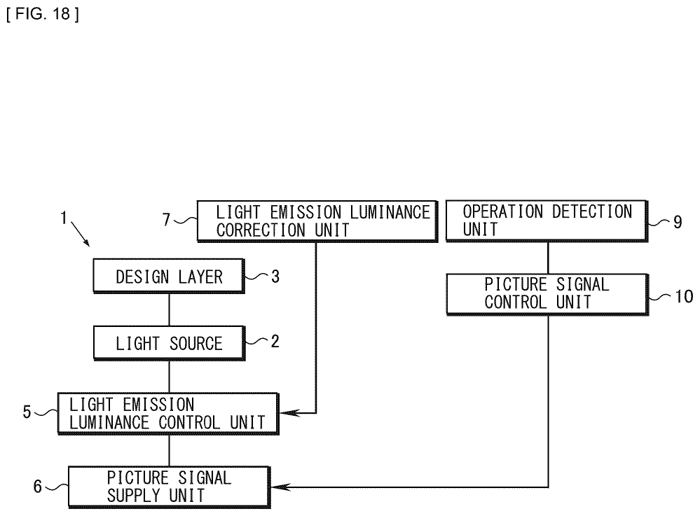

A display apparatus 1 according to a fifth embodiment of the present disclosure will be described with reference to FIGS. 18 to 20.

### [Configuration of Display Apparatus 1]

FIG. 18 illustrates an example of an overall configuration of the display apparatus 1 according to the fifth embodiment. The display apparatus 1 according to the fifth embodiment corresponds to the display apparatus 1 according to the third embodiment further including an operation detection unit 9 and a picture signal control unit 10.

The operation detection unit 9 detects an operation of the viewer H at a position of the design layer 3 in the display apparatus 1. For example, the operation detection unit 9 detects a change of a viewing position of the viewer H with respect to the position of the design layer 3. It is possible to practically use a camera, a sensor, or the like that detects a change in the position of the viewer H in the operation detection unit 9. The picture signal control unit 10 controls a picture signal to be supplied from the picture signal supply unit 6 to the light emission luminance control unit 5 in response to the viewer H's operation detected by the operation detection unit 9. For example, the picture signal control unit 10 causes a picture signal supplied from the picture signal supply unit 6 to have interactivity in response to the change in the viewing position of the viewer H.

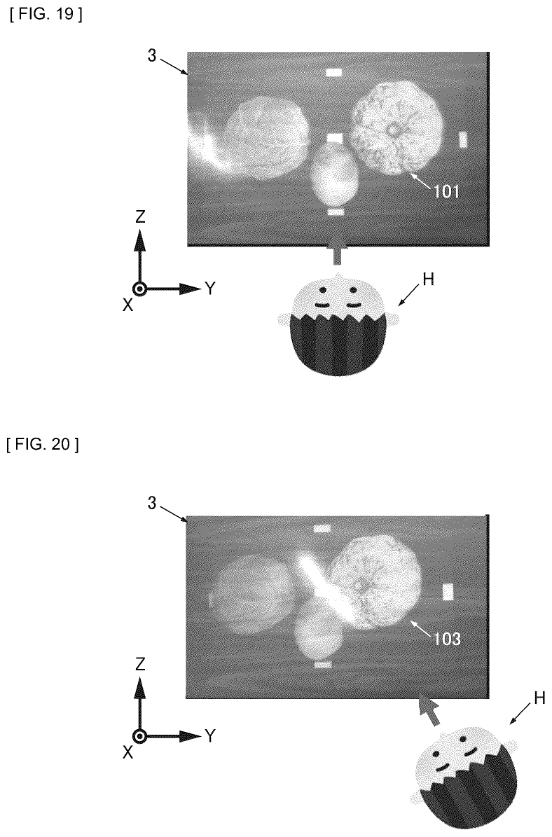

FIG. 19 illustrates an example of a display state of the design layer 3 when the viewer H view/listens to the display apparatus 1 from the front direction. FIG. 20 illustrates an example of a display state of the design layer 3 when the viewer views/listens to the display apparatus 1 from a front and oblique direction. As illustrated in FIG. 19, the viewer H is viewing to the optical information 101 displayed in the design layer 3 in the display apparatus 1. Here, the viewer H moves from an initial viewing position to the right side (in the Y arrow direction). The change in the viewing position of the viewer H is detected by the operation detection unit 9. The operation detection unit 9 transmits change information of the viewing position of the viewer H to the picture signal control unit 10. The picture signal control unit 10 controls the picture signal from the picture signal supply unit 6 on the basis of the change information of the viewing position of the viewer H. As illustrated in FIG. 20, optical information 103 as if viewed from a direction after movement of the viewing position of the viewer H is displayed in the design layer 3.

Constituent elements other than the above-mentioned constituent elements are identical or substantially identical to those of the display apparatus 1 according to the third embodiment.

### [Actions and Effects]

The display apparatus 1 according to the fifth embodiment enables obtaining of actions and effects similar to those obtained by the display apparatus 1 according to the third embodiment.

Additionally, the display apparatus 1 includes the operation detection unit 9 and the picture signal control unit 10 as illustrated in FIG. 18. The operation detection unit 9 detects an operation of the viewer H. The picture signal control unit 10 controls the picture signal supplied from the picture signal supply unit 6 in response to the viewer H's operation detected by the operation detection unit 9. Hence, it is possible for the display apparatus 1 to display the optical information 103 having interactivity in the design layer 3, in response to the operation of the viewer H, as illustrated in FIGS. 19 and 20,

### 6. Sixth Embodiment

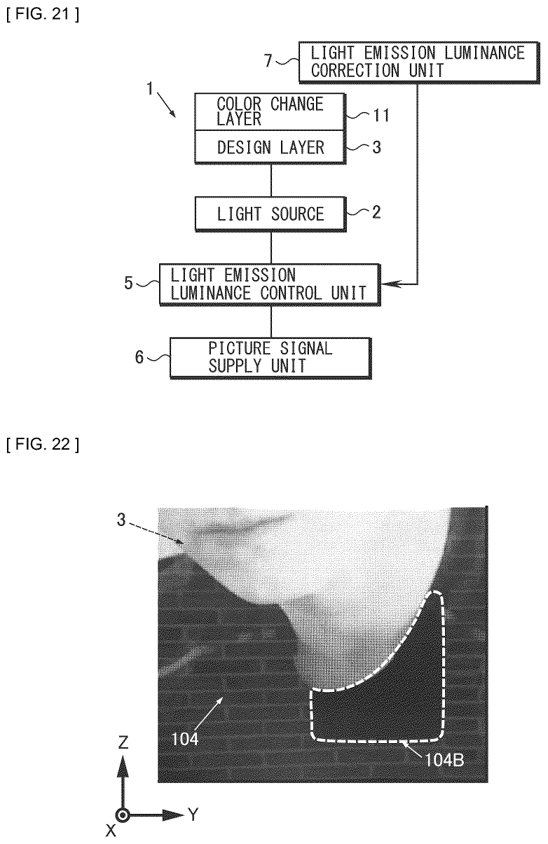

A display apparatus 1 according to a sixth embodiment of the present disclosure will be described with reference to FIGS. 21 to 22.

### [Configuration of Display Apparatus 1]

FIG. 21 illustrates an example of an overall configuration of the display apparatus 1 according to the sixth embodiment. FIG. 22 illustrates an example of a display state of the design layer 3 in the display apparatus 1. The display apparatus 1 according to the sixth embodiment corresponds to the display apparatus 1 according to the third embodiment further including a color change layer 11. The color change layer 11 is disposed on the design layer 3 on the opposite side of the light source 2. Additionally, a light passage region that is similar to the light passage region 31 in the design layer 3 is disposed in the color change layer 11.

The color change layer 11 changes in color due to a temperature change in the sixth embodiment. More specifically, in the color change layer 11, for example, paint that changes from transparent to black when a temperature increases. Light emitted from the light source 2 is used for temperature control of the design layer 3. That is, when the display apparatus 1 is powered ON and starts to perform display, it is possible to gradually increase a temperature of the design layer 3 after the elapse of a predetermined time period especially without use of a heating apparatus.

### Examples

Special ink, “Metamocolor (registered trademark)” manufactured by Pilot Corp., was used in the color change layer 11. This special ink changes from transparent to black or from black to transparent with a boundary temperature of about 30° C. The design layer 11 was formed by printing of the above-mentioned special ink twice. The display apparatus 1 that adopted the above-mentioned color change layer 11 vividly displayed black 104B in optical information 104 as illustrated in FIG. 22.

Constituent elements other than the above-mentioned constituent elements are identical or substantially identical to those of the display apparatus 1 according to the third embodiment.

### [Actions and Effects]

The display apparatus 1 according to the sixth embodiment enables obtaining of actions and effects similar to those obtained by the display apparatus 1 according to the third embodiment.

Additionally, the display apparatus 1 includes the color change layer 11, as illustrated in FIG. 21. The color change layer 11 is disposed on the design layer 3 on the opposite side of the light source 2, and changes in color due to a temperature change. In this configuration, the color change layer 11 changes from transparent to black and from black to transparent. For this reason, the color change layer 11 is in a transparent state at the time of non-display of the display apparatus 1, and thus neither gives the sense of presence of the display apparatus 1 nor interferes with the design of the design layer 3 (for example, a color and a texture). Additionally, it is possible for the display apparatus 1 to display, as the optical information 104, a vivid image or a vivid video picture expressing the black 104B with the color change layer 11, as illustrated in FIG. 22. For example, it is possible for the display apparatus 1 to display blackness when displaying the optical information 104 with a large amount of black such as a movie.

### 7. Seventh Embodiment

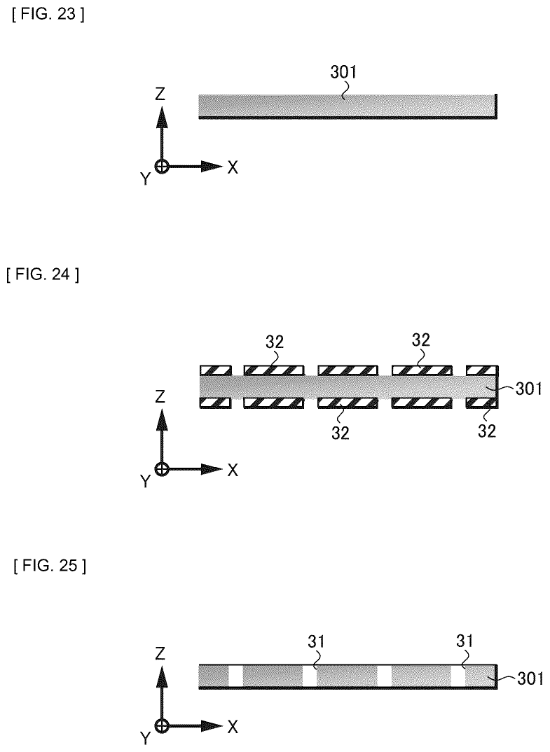

A display apparatus 1 according to a seventh embodiment of the present disclosure will be described with reference to FIGS. 23 to 28. In the seventh embodiment, a description will be given of a method of manufacturing the design layer 3 that constitutes the display apparatus 1.

### [Method of Manufacturing Design Layer 3]

FIGS. 23 to 26 each illustrate an example of a step cross section for describing the method of manufacturing the design layer 3. FIGS. 27 to 28 each illustrate an example of a step plane for describing the method of manufacturing the design layer 3.

First, the base 301 for the design layer 3 is prepared, as illustrated in FIG. 23. As the base 301, for example, a metal plate such as a stainless-steel plate is used. As illustrated in FIG. 24, a mask 32 is formed on the base 301. The mask 32 includes an aperture at a position corresponding to the light passage region 31. As the mask 32, it is possible to practically use a photoresist mask formed by, for example, photolithography.

Etching processing is performed on the base 301 with the mask 32. In the etching processing, for example, a medicinal solution is used. The medicinal solution corrodes a region exposed from the mask 32 in the base 301. After the end of the etching processing, the light passage regions 31 are formed from light passage holes penetrating the base 301 in the thickness direction (refer to FIGS. 25 and 27). Thereafter, as illustrated in FIGS. 25 and 27, the mask 32 is removed. After the mask 32 is removed, the base 301 including the light passage regions 31 is completed.

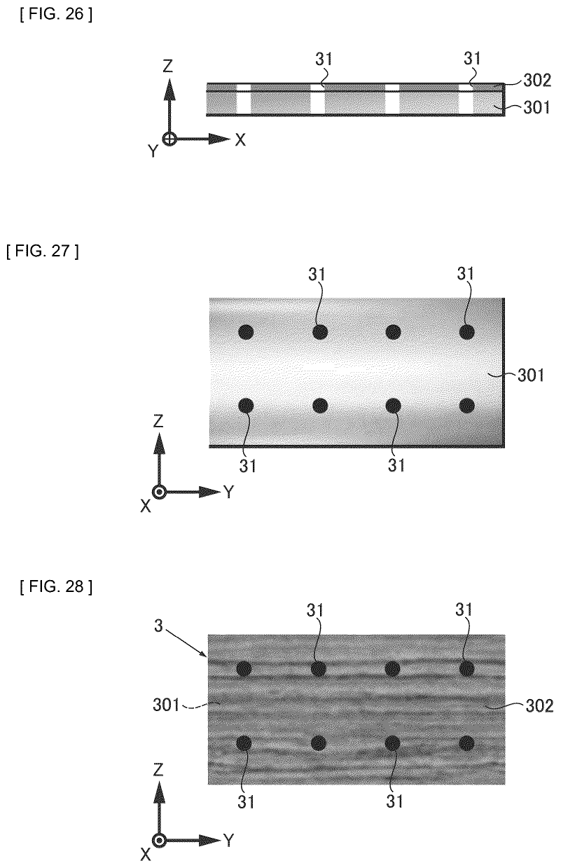

As illustrated in FIGS. 26 and 28, the design 302 is formed on the surface of the base 301 by printing (or coating). At this time, the design 302 is selectively printed only on the surface of the base 301. After the end of a series of steps, the design layer 3 including the base 301 and the design 302 is formed.

Constituent elements other than the above-mentioned constituent elements are identical or substantially identical to those of the display apparatus 1 according to the third embodiment.

### [Actions and Effects]

The display apparatus 1 according to the seventh embodiment enables obtaining of actions and effects similar to those obtained by the display apparatus 1 according to the third embodiment.

Additionally, the design layer 3 that constitutes the display apparatus 1 includes the base 301 and the design 302 as described in the manufacturing method illustrated in FIGS. 23 to 28. The base 301 includes the light passage regions 31 formed from the light passage holes penetrating the base 301 in the thickness direction. The design 302 is printed on the base 301. In the design layer 3, as described above, the light passage regions 31 are formed by photolithography or etching processing. Hence, it is possible to implement a fine aperture dimension of each light passage region 31, a minute array pitch, and increased accuracy. Additionally, it is possible to implement mass-production of the design layer 3. Furthermore, it is possible to manufacture the design layer 3 at a low price.

Additionally, since the design 302 is formed by printing in the design layer 3, it is possible to easily form the design 302 having various colors and various patterns. Hence, it is possible to easily manufacture a custom-made design layer 3 in which a design corresponding to a design in an environment is made.

### 8. Other Embodiments

The present technology is not limited to the above-mentioned embodiments, and it is possible to make various modifications without departing from the scope of the present technology. For example, it is possible to construct a display apparatus that combines two or more embodiments and that is not described above.

A display apparatus according to one embodiment of the present disclosure includes: a light source that emits light; a design layer that is disposed to oppose the light source, and in which a design is made on at least a surface of the design layer, the surface being on an opposite side of the light source; a light passage region that is disposed in the design layer at a position corresponding to the light source, that causes light emitted from the light source to pass therethrough, and that is visually unrecognizable at a viewing distance; a light emission luminance control unit that controls light emission luminance of the light that is emitted from the light source and that passes through the light passage region to be more than or equal to a value obtained by multiplication of average design layer luminance of the design layer by an allowable limit value that causes the design to disappear. Furthermore, in the display apparatus according to one embodiment, the light emission luminance control unit performs control to satisfy the following expression.

Light emission luminance≥allowable limit value×average design layer luminance

With such a configuration, it is possible for the display apparatus to prevent interference with the design at the time of non-display and display a vivid image or a vivid video picture without being influenced by the design.

### <Configuration of Present Technology>

The present technology includes the following configurations. With the following configurations, it is possible to provide the display apparatus that prevents interference with the design at the time of non-display and enables display of a vivid image or a vivid video picture without being influenced by the design.

(1)

A display apparatus including:
a light source that emits light;
a design layer that is disposed to oppose the light source, and in which a design is made on at least a surface of the design layer, the surface being on an opposite side of the light source;
a light passage region that is disposed in the design layer at a position corresponding to the light source, that causes light emitted from the light source to pass therethrough, and that is visually unrecognizable at a viewing distance; and
a light emission luminance control unit that controls light emission luminance of the light that is emitted from the light source and that passes through the light passage region to be more than or equal to a value obtained by multiplication of average design layer luminance of the design layer by an allowable limit value that causes the design to disappear.
   (2)

The display apparatus according to (1), in which the light emission luminance control unit performs control to satisfy an expression of the light emission luminance≥the allowable limit value×the average design layer luminance.

(3)

The display apparatus according to (1) or (2), in which the light passage region has a light passage hole formed in at least a portion of the design layer in a thickness direction, or a light transmission part that is disposed in at least a portion of the design layer in the thickness direction and that has light transmittivity that is higher than light transmittivity of the design layer.

(4)

The display apparatus according to any one of (1) to (3), in which the design layer includes:
a base having the light transmittivity that is higher than the light transmittivity of the design layer at least at a position corresponding to the light source; and
the design formed in the base.
   (5)

The display apparatus according to any one of (1) to (4), in which the design includes at least one or more selected from a color, a pattern, a wood grain, marble, and metal.

(6)

The display apparatus according to any one of (1) to (5), in which the light source includes at least one or more selected from a light-emitting diode array, a liquid crystal display, and an organic electroluminescent (EL) display.

(7)

The display apparatus according to any one of (1) to (6), in which the allowable limit value is 6 or more and 7 or less.

(8)

The display apparatus according to any one of (1) to (7), in which, when eyesight of a viewer is “1” and a viewing distance is “V”, an aperture ratio of the light passage region is less than 31%.

(9)

The display apparatus according to any one of (1) to (8), further including: a picture signal supply unit that supplies, to the light emission luminance control unit, a picture signal to be superimposed on the design of the design layer.

(10)

The display apparatus according to any one of (1) to (9), further including: a light emission luminance correction unit that measures at least one or more selected from the average design layer luminance, environmental illuminance around the design layer, and reflectance of the design layer, and that corrects the light emission luminance.

(11)

The display apparatus according to any one of (1) to (10), further including: a light condensing optical system that is disposed between the light source and the design layer and that increases luminance of the light emitted from the light source.

(12)

The display apparatus according to (11), in which the light condensing optical system is one or more selected from a light guiding fiber, a condensing lens, a dual luminance enhancement film, a condensing mirror, and a mirror aperture.

(13)

The display apparatus according to (9), further including:
an operation detection unit that detects a viewer's operation; and
a picture signal control unit that controls the picture signal to be supplied from the picture signal supply unit to the light emission luminance control unit in response to the viewer's operation detected by the operation detection unit.
   (14)

The display apparatus according to any one of (1) to (13), further including a color change layer that is provided on the design layer on an opposite side of the light source and that changes in color due to a temperature change.

(15)

The display apparatus according to (1) or (2), in which the design layer includes:
a base having the light passage region formed from a light passage hole that penetrates in a thickness direction; and
the design printed on the base.

The present application claims the benefit of Japanese Priority Patent Application JP2022-091735 filed with the Japan Patent Office on Jun. 6, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A display apparatus comprising:
a light source that emits light;
a design layer that is disposed to oppose the light source, and in which a design is made on at least a surface of the design layer, the surface being on an opposite side of the light source;
a light passage region that is disposed in the design layer at a position corresponding to the light source, that causes light emitted from the light source to pass therethrough, and that is visually unrecognizable at a viewing distance; and
a light emission luminance control unit that controls light emission luminance of the light that is emitted from the light source and that passes through the light passage region to be more than or equal to a value obtained by multiplication of average design layer luminance of the design layer by an allowable limit value that causes the design to disappear.

2. The display apparatus according to claim 1, wherein the light emission luminance control unit performs control to satisfy an expression of the light emission luminance≥the allowable limit value×the average design layer luminance.

3. The display apparatus according to claim 1, wherein the light passage region has a light passage hole formed in at least a portion of the design layer in a thickness direction, or a light transmission part that is disposed in at least a portion of the design layer in the thickness direction and that has light transmittivity that is higher than light transmittivity of the design layer.

4. The display apparatus according to claim 3, wherein the design layer includes:
a base having the light transmittivity that is higher than the light transmittivity of the design layer at least at a position corresponding to the light source; and
the design formed in the base.

5. The display apparatus according to claim 1, wherein the design includes at least one or more selected from a color, a pattern, a wood grain, marble, and metal.

6. The display apparatus according to claim 1, wherein the light source includes at least one or more selected from a light-emitting diode array, a liquid crystal display, and an organic electroluminescent display.

7. The display apparatus according to claim 1, wherein the allowable limit value is 6 or more and 7 or less.

8. The display apparatus according to claim 1, wherein, when eyesight of a viewer is “1” and a viewing distance is “V”, an aperture ratio of the light passage region is less than 31%.

9. The display apparatus according to claim 1, further comprising a picture signal supply unit that supplies, to the light emission luminance control unit, a picture signal to be superimposed on the design of the design layer.

10. The display apparatus according to claim 1, further comprising a light emission luminance correction unit that measures at least one or more selected from the average design layer luminance, environmental illuminance around the design layer, and reflectance of the design layer, and that corrects the light emission luminance.

11. The display apparatus according to claim 1, further comprising a light condensing optical system that is disposed between the light source and the design layer and that increases luminance of the light emitted from the light source.

12. The display apparatus according to claim 11, wherein the light condensing optical system comprises one or more selected from a light guiding fiber, a condensing lens, a dual luminance enhancement film, a condensing mirror, and a mirror aperture.

13. The display apparatus according to claim 9, further comprising:
an operation detection unit that detects a viewer's operation; and
a picture signal control unit that controls the picture signal to be supplied from the picture signal supply unit to the light emission luminance control unit in response to the viewer's operation detected by the operation detection unit.

14. The display apparatus according to claim 1, further comprising a color change layer that is provided on the design layer on an opposite side of the light source and that changes in color due to a temperature change.

15. The display apparatus according to claim 1, wherein the design layer includes:
a base having the light passage region formed from a light passage hole that penetrates in a thickness direction; and
the design printed on the base.
